(19) United States
(12) Patent Application Publication
(10) Pub. No.: US 2015/0069667 A1
(43) Pub. Date: Mar. 12, 2015

(54) Nano-parts fabrication method

(71) Applicants: Yi Li, Ann Arbor, MI (US); Jieran Li, Ann Arbor, MI (US); Wen Lu, Shenzhen (CN)

(72) Inventors: Yi Li, Ann Arbor, MI (US); Jieran Li, Ann Arbor, MI (US); Wen Lu, Shenzhen (CN)

(21) Appl. No.: 13/987,879

(22) Filed: Sep. 12, 2013

(51) Int. Cl. C23C 14/46; C23C 14/08; C23C 14/14; C23C 14/00

(52) U.S. Cl. CPC C23C 14/46; C23C 14/0005; C23C 14/08; C23C 14/14
USPC 264/442; 204/192.11; 264/81; 264/334

(57) ABSTRACT

Embodiments of present invention provide a method of forming nano-parts through vacuum coating technology. The method includes creating a set of openings in a substrate, the set of openings having a set of shapes that are complimentary to shapes of a set of nano-parts and the nano-parts having a size between 1 nm and 1000 nm; lining the set of openings with a thin layer of oleic acid of a single molecule thickness; depositing a metal-oxide material inside the set of openings to form the set of nano-parts; immersing the substrate together with the set of nano-parts in a solution; applying a supersonic vibration to the substrate via the solution causing the set of nano-parts to detach from the substrate; and separating the set of nano-parts from the substrate.

### FIELD OF THE INVENTION

The present invention relates to a method of fabricating small mechanical parts or particles. More particularly, it relates to manufacturing parts of nanometer scale through an optical thin-film depositing and coating technology.

### BACKGROUND

With the continuing scaling in device making, small tiny mechanical parts are in high demand in order to be able to fit into tiny real estate space, whether it is for bio-medical applications such as artificial parts embedded inside human body to replace failed or non-functional human body parts or industrial applications such as micro parts fabrication, or miniature parts used in semiconductors, micro robots etc. For example, with MEMS (micro-electro-mechanical systems) switches starting to be used in, for example, television display and other electronic control systems, small mechanical parts and/or particles, whose size is often in the order of a few nanometers (nm) to a few micrometers (um) or sometimes from sub-nanometer to some tens of micrometers are often required to be manufactured in such a way that satisfies their specific application needs.

### SUMMARY

This invention provides a new method of creating or making tiny mechanical parts through the vacuum coating and/or deposition technology. More specifically, embodiments of present invention provide a method of fabricating small mechanical parts or particles of nanometer scale known herein as nano-parts, through precision optical thin film deposition and/or coating technique. The precision optical thin film coating process may include, but not limited to, an EBD (Electron-Beam Deposition) process, an IAD (Ion-Assisted Deposition) process including PIAD (Plasma-Ion-Assisted Deposition) process, an IBS (Ion-Beam Sputtering) process, etc. The material deposited may include metal or metal-oxide, and the precision thin film deposition/coating process may be able to control the rate of deposition up to sub-nanometer to around a few nanometers range. Before deposition, standard lithographic patterning process commonly used in semiconductor industry may be applied to create one or more openings in a substrate corresponding to shapes of one or more nano-parts to be made. In other words, a mold may be created out of the substrate that takes the shapes of one or more nano-parts to be manufactured. The metal or metal-oxide material may then be applied to the substrate mold, layer-by-layer, through a deposition and/or coating process. After removing unwanted coating material in areas outside the openings of nano-parts shapes, the tiny mechanical parts of nano-meter range size may be separated from the substrate.

More specifically, embodiments of the present invention provide a method which includes having a first set of shapes defining a set of particles, the set of particles being less than one micrometer in size; creating a set of openings in a substrate, the set of openings having a second set of shapes that are complimentary to the first set of shapes of the set of particles; filling the set of openings with a material through a deposition process to form the set of particles; and separating the set of particles from the substrate.

In one embodiment, the method further includes applying a thin layer of non-adhesive material to a top surface of the set of openings before filling the set of openings with the material. In one instance, the thin layer of non-adhesive material is a thin layer of oleic acid being applied to the set of openings, through a spin-on process, and having a thickness of a single layer of molecules of the oleic acid.

In one embodiment, separating the set of particles from the substrate includes applying a supersonic vibration to the substrate, the vibration causing the set of particles to detach from a surface of the set of openings in the substrate. In one instance, applying the supersonic vibration to the substrate further includes immersing the substrate in a solution, the solution conveying the supersonic vibration to the substrate.

In another embodiment, separating the set of particles from the substrate further includes removing the material that are above a top surface level of the substrate by a chemical-mechanic-polishing process, the removing ensuring that the set of particles are not connected to each other by the material.

In yet another embodiment, filling the set of openings with the material includes applying a physical vapor deposition (PVD) process to deposit the material layer-by-layer on top of a surface of the set of openings in the substrate.

In a further embodiment, the set of particles has a size larger than 1 nm.

### BRIEF DESCRIPTION OF THE DRAWINGS

The present invention will be understood and appreciated more fully from the following detailed description of embodiments of the invention, taken in conjunction with the accompanying drawings of which:

FIG. 1 is a demonstrative illustration of top and cross-sectional views of a template manufactured for making nano-parts according to one embodiment of present invention;

FIG. 2 is a demonstrative illustration of a cross-sectional view of a step of a method of making nano-parts according to one embodiment of present invention;

FIG. 3 is a demonstrative illustration of a cross-sectional view of a step of a method of making nano-parts according to another embodiment of present invention;

FIG. 4 is a demonstrative illustration of a cross-sectional view of a step of a method of making nano-parts according to yet another embodiment of present invention;

FIG. 5 is a demonstrative illustration of a method of making nano-parts through an electron-beam deposition process according to one embodiment of present invention;

FIG. 6 is a demonstrative illustration of a method of making nano-parts through an ion-assisted deposition process according to another embodiment of present invention; and

FIG. 7 is a demonstrative illustration of a method of making nano-parts through an ion-beam sputtering deposition process according to yet another embodiment of present invention.

It will be appreciated that for simplicity and clarity of illustration, elements shown in the figures have not necessarily been drawn to scale. For example, the dimensions of some of the elements may be exaggerated relative to other elements for clarity.

### DETAILED DESCRIPTION OF EMBODIMENTS

In the following detailed description, numerous specific details are set forth in order to provide a thorough understanding of various embodiments of present invention. However it will be understood by those of ordinary skill in the art that embodiments of present invention may be practiced without these specific details. In other instances, well-known details of structure and method of use or operation may not be described in detail in order not to obscure description of embodiments of the present invention.

Some portions of the detailed description in the following may be presented in terms of algorithms and/or symbolic representations of operations. These algorithmic descriptions and representations may be the techniques used by those skilled in the arts to convey the substance of their work to others skilled in the art.

In the following description, various figures, diagrams, flowcharts, models, and descriptions may be presented as different means to effectively convey the substances and illustrate different embodiments of the invention that are proposed in this application. It shall be understood by those skilled in the art that they are provided merely as exemplary and/or demonstrative samples, and shall not be constructed as limitation to the invention.

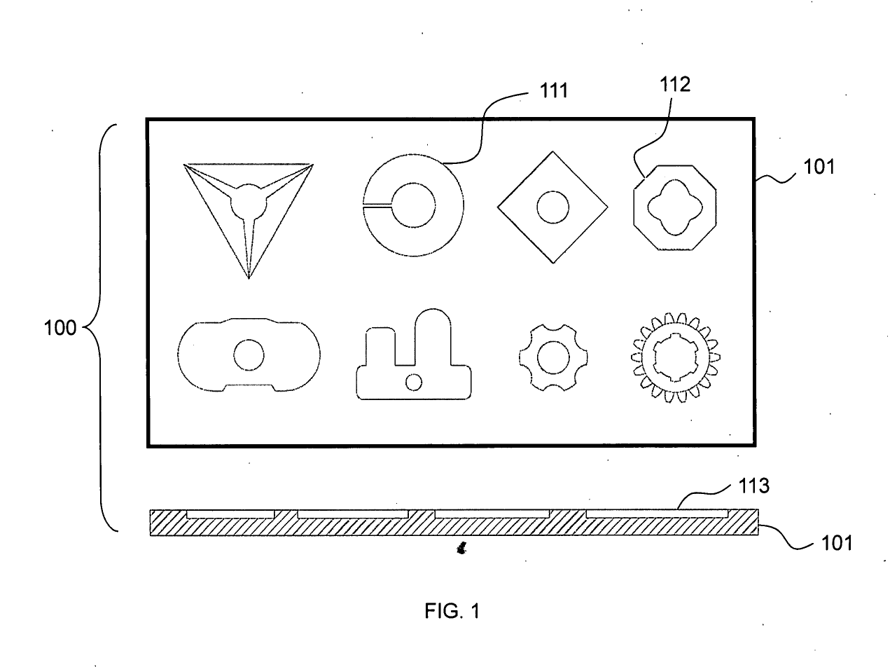

FIG. 1 is a demonstrative illustration of top and cross-sectional views of a template manufactured for making nano-parts according to one embodiment of present invention. More specifically, one embodiment of present invention may include determining or defining a set of small parts or particles, that may be nanometer-to-micrometer in size, and determining or defining their corresponding shapes. These small parts or particles may sometimes be referred to hereinafter as nano-parts as well. One embodiment of the method may further include preparing a template or a mold 100 which includes one or more shapes, such as shapes 111, 112, and 113, to name a few, and others as being demonstratively illustrated in FIG. 1 that are formed in a substrate 101. Shapes 111, 112, and 113 are complementary shapes to those of the set of nano-parts and thus may equally be significantly small in size, in the order of a few nanometers (nm) or even sub-nanometer to hundreds of nanometers. For example, shapes 111, 112, and 113 may have a size from 1 nm to 1000 nm (1 um). However, a person skilled in the art will appreciate that embodiments of present invention are not limited in this aspect and the size of these shapes may sometimes be up to a few micrometers (um) such as around 10 um. Shapes 111, 112, and 113 in mold 100, as being discussed above, are complementary shapes to these small mechanical parts or particles (nano-parts) to be manufactured. Corresponding to these nano-parts, shapes 111, 112, and 113 may thus be referred to as nano-scale shapes.

Shapes 111, 112, and 113 are three-dimensional in nature, to have their respective depths and lateral dimensions that may be collectively referred to herein as “sizes” and in particular a lateral dimension may be defined as size of the shape throughout this application. Shapes 111, 112, and 113 may be formed for example through an etching process into substrate 101. For example, as some non-limiting examples, one shape may have the shape of a “nut” and another may have the shape of a “washer”, similar to those that are often used in general mechanics as fastener. Substrate 101 may be a semiconductor substrate, a glass substrate, a ceramic substrate, a metal substrate, or any other substrate of suitable material and suitable for the manufacturing process as being described below in more details.

In one embodiment, shapes 111, 112, and/or 113 may be formed inside substrate 101, directly below a surface thereof, by applying a standard photolithographic patterning process as such patterning process is known in the art and well established in the semiconductor industry. In another embodiment, shapes 111, 112, and/or 113 may be etched into the surface of substrate 101 through a laser blazing process. It is expected that sizes of these shapes may be affected and/or sometimes determined by the particular process and/or tools used in the creation thereof. Other currently existing or future developed processes, such as an electronic beam (e-beam) exposure process, are fully contemplated here, together with the various sizes of shapes that are offered or made available by these processes.

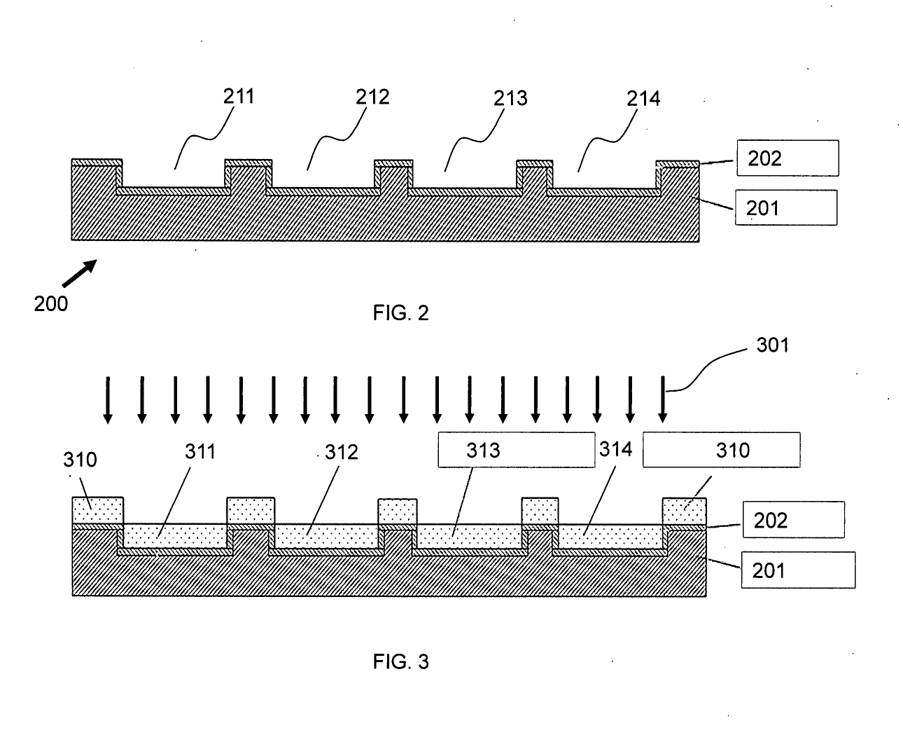

FIG. 2 is a demonstrative illustration of a cross-sectional view of a step of a method of making nano-parts according to one embodiment of present invention. More specifically, the method includes patterning a substrate 201 to have a plurality (including one) of openings 211, 212, 213, and 214 having shapes representing a plurality of parts or particles of nano-meter scale. In other words, openings 211, 212, 213, and 214 represent complimentary shapes of a plurality of nano-parts to be manufactured. According to one embodiment of present invention, after substrate 201 being patterned to have the plurality or set of openings 211, 212, 213, and 214 on top thereof, thereby forming template or mold 200, substrate 201 may subsequently be exposed to, or subjected to, a surface treatment process which cleans and keeps clean of the surface area of substrate 201 particularly the surface area of openings 211, 212, 213, and 214.

According to one embodiment, following the cleaning, a thin layer of non-adhesive material 202 such as, for example, a thin film or thin layer of oil such as an oleic acid may be applied to the clean surface of substrate 201 including top surface areas of openings 211, 212, 213, and 214. The oleic acid 202 may preferably be spread or applied, in a thickness of single layer of molecules, to openings 211, 212, 213, and 214 in a spin-on process for example, thus lining openings 211, 212, 213, and 214. The thin oleic acid film 202 of single molecule layer thickness may help remove, detach, and/or separate from substrate 201 nano-parts that, as being described below in more details, may be formed inside opening shapes 211, 212, 213, and 214 in later process steps.

FIG. 3 is a demonstrative illustration of a cross-sectional view of a step of a method of making nano-parts according to another embodiment of present invention. More specifically, the method includes forming a layer of suitable or desired material such as metal or non-metal materials through a deposition process 301 into nano-scale shapes 211, 212, 213, and 214 to form their corresponding nano-parts 311, 312, 313, and 314. The deposition process 301 may include, for example, a physical vapor deposition (PVD) process or an ion-beam sputtering (IBS) process. The physical vapor deposition may further include, for example, an electronic-beam deposition (EBD) process, an ion-assisted deposition (IAD) process, or an plasma-ion-assisted deposition (PIAD) process, to name a few. Other thin-film deposition processes or coating processes may be used as well.

The above various deposition processes or techniques may be used to form nano-parts 311, 312, 313, and 314 with proper metal or non-metal material (such as metal-oxide) being deposited or coated in a layer-by-layer process inside openings 211, 212, 213, and 214 created in template 200. Template 200 is the host of openings of nano-scale shapes 211, 212, 213, and 214. As being described above, nano-scale shapes 211, 212, 213, and 214 correspond to and have complimentary shapes of nano-parts 311, 312, 313, and 314 of under manufacturing.

Nano-parts 311, 312, 313, and 314 may be deposited to have a height either below or above a top surface of substrate 201. Coating material deposited directly above the top surface of substrate 201, such as 310 in FIG. 3, may be partially connected to nano-parts 311, 312, 313, and 314. For example, in a conformal deposition process of making nano-parts 311, 312, 313, and 314, coating material 310 on the top surface of substrate 201 may be part of a conformal layer, and the conformal layer may include nano-parts 311, 312, 313, and 313 as well as any material in-between the nano-parts and/or the coating material 310. On the other hand, in a directional deposition process, in particular when thickness of the finally formed nano-parts 311, 312, 313, and 314 is made to be less than the height of substrate 201, having a thickness less than the depth of the openings, coating material 310 may be “isolated” on top of substrate 201 in areas other than any openings, and separated from or at least not substantially connected to the finally formed nano-parts 311, 312, 313, and 314.

With a regular PVD processing technology, a target material, such as metal or non-metal material that may purposely be selected based upon any specific requirement for forming nano-parts 311-314, may first be determined. The target material is then heated up inside a vacuum chamber by an electrical resistor or through electron bombardment until the temperature of target material has reached to an evaporating or subliming point. Atoms and/or molecules may then escape from the target material and are deposited onto the surface, where openings 211, 212, 213, and 214 are formed, of template 200. During the PVD deposition process, specific conditions such as ambient temperature, pressure of chamber, and time duration may be varied and/or controlled to achieve adjustment in the rate of deposition. For example, the rate of deposition may be adjusted to be from about 0.1 nm per second (nm/s) to about 1.5 nm/s. Furthermore, with the help of a quartz crystal oscillate film thickness controller, thickness of deposited film may be controlled to within 10 nm to 10 um at an accuracy of less than a few nanometers.

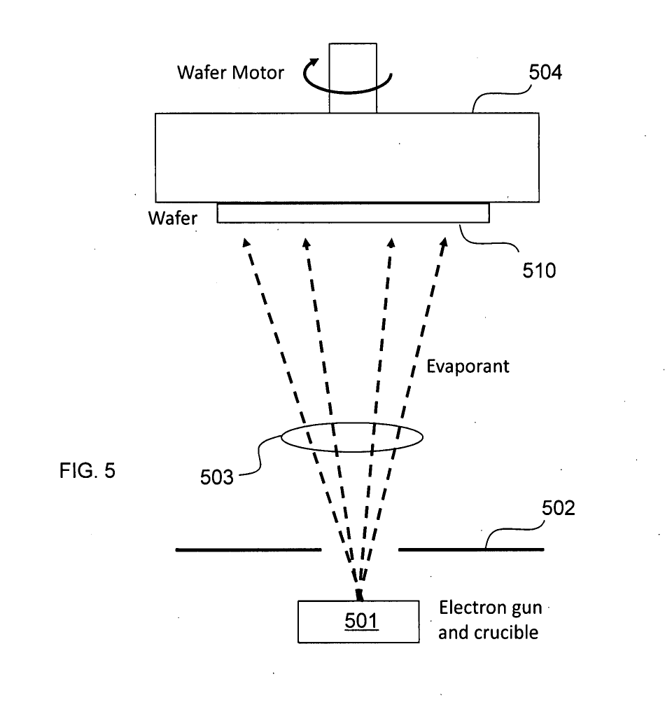

Reference is briefly made to FIG. 5, which is a demonstrative illustration of a method of making nano-parts through an electron-beam deposition process according to one embodiment of present invention. More specifically, the electron-beam deposition (EBD) process may be performed inside a vacuum chamber. The chamber may contain a crucible 501, with which an electron-beam generated from a hot filament is focused via a magnetic field onto a copper hearth that is filled with material to be evaporated, which may be a metal or other non-metal material such as a metal oxide. The electron beam heats the material, causing it to evaporate, radiate and condense on all surfaces inside the vacuum chamber that are in a direct line of sight 503 of crucible 501. Furthermore, a rotating substrate holder 504 may be used to keep substrate 201, which is wafer 510 in FIG. 5, in a horizontal plane and a shutter 502 may be used to stop the deposition and/or coating process when the desired film thickness has been achieved. The substrate 201 may be heated to a temperature of 150˜300 degree C. to help the nucleation of the material.

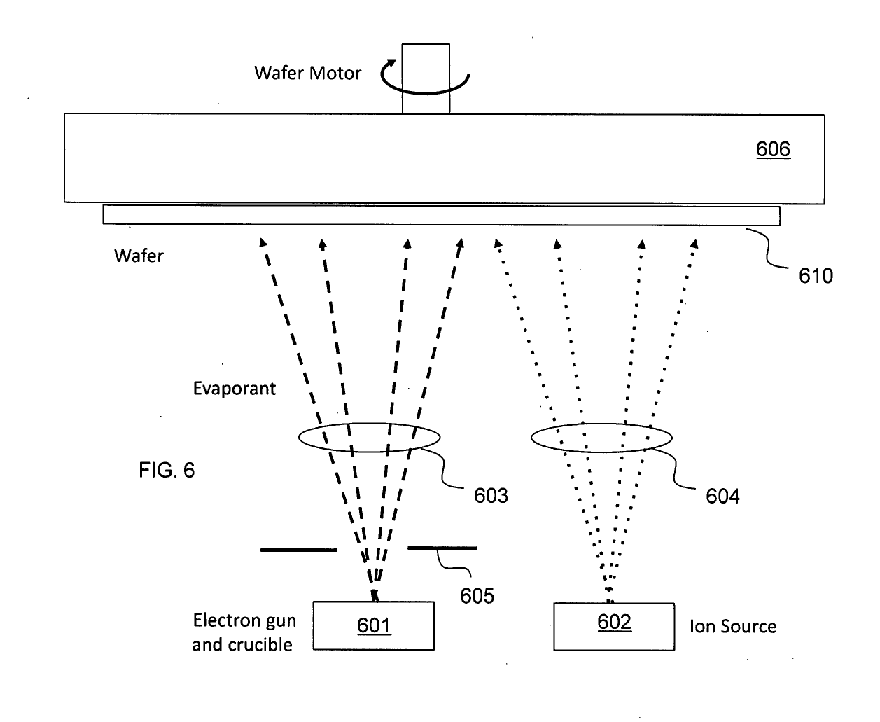

FIG. 6 is a demonstrative illustration of a method of making nano-parts through an ion-assisted deposition process according to another embodiment of present invention. More specifically, similar to the electron-beam deposition process as being illustrated in FIG. 5, ion-assisted deposition (IAD) process may be performed inside a chamber as well, and uses a crucible 601 to generate evaporant 603 of the material that are selected to be deposited. The IAD process further has a substrate holder 606 holding wafer 610, which is substrate 201, and uses a shutter 605 to control the amount of deposition. Different from the EBD process described above, the IAD process uses an ion source 602 to increase the activation energy of the deposited material, which results in a denser and more uniform film being formed on the surface of substrate 201. More specifically, the IAD process uses an ion gun 602 to bombard the surface of substrate 201 (610) with a flux of high-energy ions 604 composed of oxygen and/or argon gas. The bombardment by this energetic beam is similar to atomic shot peering, which helps producing a denser film.

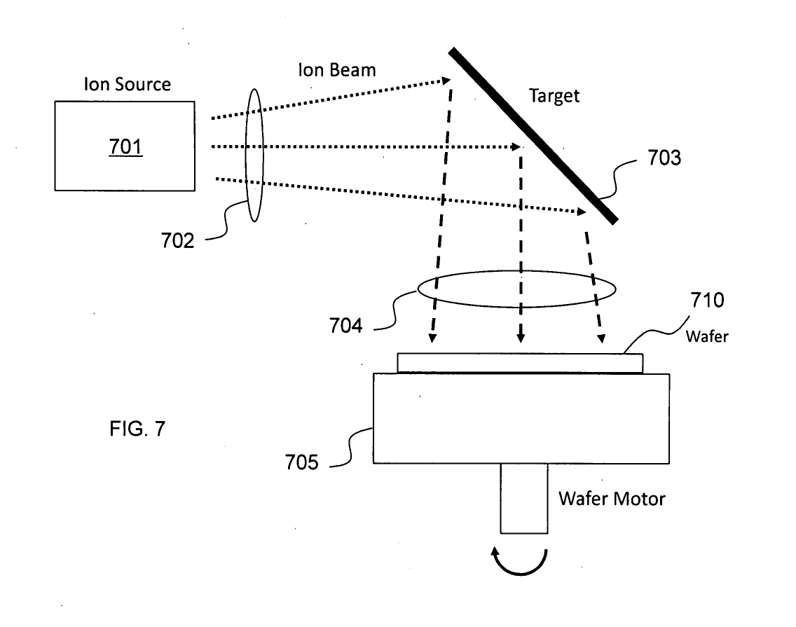

FIG. 7 is a demonstrative illustration of a method of making nano-parts through an ion-beam sputtering deposition process according to yet another embodiment of present invention. More specifically, the ion-beam sputtering (IBS) process may produce argon ion (Ar+) beam 702, from an ion source 701, by applying bias current of certain RF (radio frequency) to ion source 701. The argon ion beam 702 so produced may subsequently be accelerated until it possesses an energy of as high as 1000 eV, which is then applied to bombard the surface of a target material 703, which is the material selected for deposition to make nano-parts. Upon momentum transfer effect, atoms and/or molecules from target material 703 may leave surface of target material 703, forming a secondary beam 704 traveling toward a wafer 710, which in the current application is substrate 201 of template 200. With substrate 201 (710) being placed on a wafer motor 705 which facilitate the positioning of substrate relative to secondary beam 704, material from target 703 is then deposited onto opening shapes 211, 212, 213, and 214, as well as rest surface areas of substrate 201, which is illustrated in FIG. 3 as coating material 310.

Within different deposition processes such as EBD, IAD and IBS as being described above, different thickness of deposited or coated film may be achieved, through a layer-by-layer deposition or coating approach, with different accuracy control. For example, with a regular PVD process including the EBD and/or the IAD process, film thickness may generally be controlled layer-by-layer to be within about 2 nm-3 nm. In the meantime, the IBS process may be able to achieve a film thickness accuracy of up to sub-nanometer, i.e. less than 1 nm.

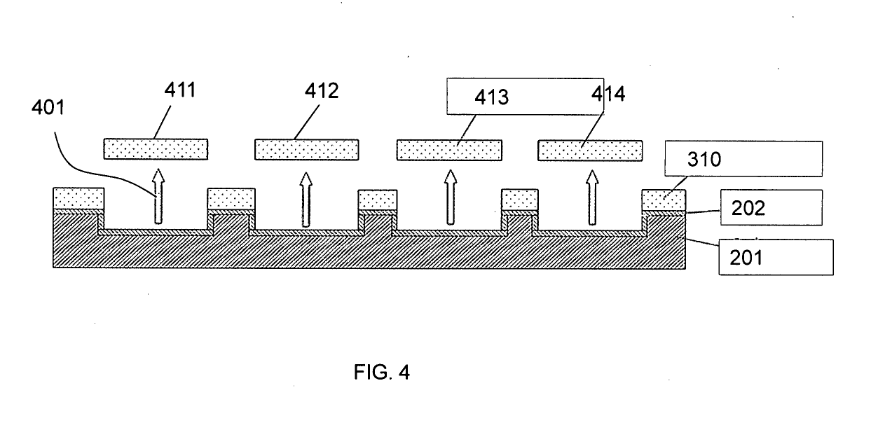

Reference is now made back to FIG. 4, which is a demonstrative illustration of a cross-sectional view of a step of a method of making nano-parts according to yet another embodiment of present invention. More specifically, after deposition of appropriate material, metal or non-metal including metal-oxide, inside opening shapes 211, 212, 213, and 214 which were made to be complementary shapes of nano-parts 311, 312, 313, and 314, nano-parts 311, 312, 313, and 314 may be separated or detached from substrate 201, or more precisely from a surface of the opening shapes 211, 212, 213, and 214.

Separating nano-parts 211, 212, 213, and 214 from substrate 201 may be achieved by applying a supersonic cleaning process 401. More specifically, substrate 201 together with nano-parts 211, 212, 213, and 214 may be immersed or soaked in a solution while the solution is being subjected to a supersonic vibration process. The vibration may be conveyed via the solution to substrate 201, thus causing nano-parts 311-314 to separate or detach from substrate 201 and become individual nano-parts 411, 412, 413, and 414.

According to another embodiment, coating material 310, which may be deposited directly on the top surface of substrate 201 in areas away from areas of openings 211, 212, 213, and 214, may be first removed in order to facilitate the separation of nano-parts 311, 312, 313, and 314 from substrate 201. The removal of coating material 310 may be made through, for example, a chemical-mechanic-polishing (CMP) process. In particular, when coating material 310 is substantially connected to nano-parts 311, 312, 313 and 314, which may be the case when formation of nano-parts 311, 312, 313, and 314 was made through in a conformal deposition process, the removal of coating material 310 may ensure that nano-parts 311, 312, 313, and 314 are separated from each other such that their separation from substrate 201 may be made with relative ease. The CMP process may remove the excessive coating material 310 as well as a top portion of material of nano-parts 311, 312, 313, and 314 that are above a top surface level of substrate 201. The CMP process thus ensures that nano-parts 311, 312, 313, and 314 have a thickness that is defined by the depths of each individual openings 211, 212, 213, and 214 created in substrate 201, and are individually separated. This helps the subsequent process of separating nano-parts 311, 312, 313, and 314 from substrate 201 through, for example, a supersonic vibration process 401 to become nano-parts 411, 412, 413, and 414 as being illustrated in FIG. 4.

While certain features of the invention have been illustrated and described herein, many modifications, substitutions, changes, and equivalents may occur to those of ordinary skill in the art. It is therefore to be understood that the appended claims are intended to cover all such modifications and changes as fall within the spirit of the invention.

What is claimed is:

1. A method comprising:
defining a first set of shapes of a set of nano-parts;
creating a set of openings in a substrate, said set of openings having a second set of shapes complimentary to said first set of shapes of said set of nano-parts;
applying a coating technique to fill up said set of openings with a metal or metal-oxide material, thereby forming said set of nano-parts; and
separating said set of nano-parts from said substrate.

2. The method of claim 1, further comprising:
applying a thin layer of non-adhesive material to said set of openings before filling said set of openings with said metal or metal-oxide material.

3. The method of claim 2, wherein applying said thin layer of non-adhesive material comprises applying a layer of oleic acid, having a thickness of a single layer of molecules of said oleic acid, to a surface of said set of openings.

4. The method of claim 1, wherein separating said set of nano-parts from said substrate comprises applying a supersonic vibration to said substrate, said vibration causing said set of nano-parts to detach from a surface of said set of openings in said substrate.

5. The method of claim 4, wherein applying said supersonic vibration to said substrate further comprises immersing said substrate in a solution to which said supersonic vibration is applied, said solution conveying said supersonic vibration to said substrate.

6. The method of claim 1, wherein applying said coating technique to fill up said set of openings comprises applying a physical vapor deposition (PVD) process to deposit said metal or metal-oxide material on top of a surface of said set of openings in said substrate.

7. The method of claim 6, wherein said PVD process is either an electron-beam deposition (EBD) process or an ion-assisted deposition (IAD) process.

8. The method of claim 1, wherein applying said coating technique to fill up said set of openings comprises applying an ion-beam sputtering (IBS) process to deposit said metal or metal-oxide material inside said set of openings.

9. The method of claim 1, wherein separating said set of nano-parts from said substrate further comprises removing said metal or metal-oxide material that are above a top surface level of said substrate by a chemical-mechanic-polishing process, said removing ensures that said set of nano-parts are not connected to each other by said metal or metal-oxide material.

10. The method of claim 1, wherein said nano-parts have a size between 1 nm and 1000 nm.

11. A method comprising:
having a first set of shapes defining a set of particles, said set of particles being less than one micrometer in size;
creating a set of openings in a substrate, said set of openings having a second set of shapes that are complimentary to said first set of shapes of said set of particles;
filling said set of openings with a material through a deposition process to form said set of particles; and
separating said set of particles from said substrate.

12. The method of claim 11, further comprising:
applying a thin layer of non-adhesive material on a top surface of said set of openings before filling said set of openings with said material.

13. The method of claim 12, wherein said thin layer of non-adhesive material is a thin layer of oleic acid being applied to said set of openings, through a spin-on process, and having a thickness of a single layer of molecules of said oleic acid.

14. The method of claim 11, wherein separating said set of particles from said substrate comprises applying a supersonic vibration to said substrate, said vibration causing said set of particles to detach from a surface of said set of openings in said substrate.

15. The method of claim 14, wherein applying said supersonic vibration to said substrate further comprises immersing said substrate in a solution, said solution conveying said supersonic vibration to said substrate.

16. The method of claim 11, wherein separating said set of particles from said substrate further comprises removing said material that are above a top surface level of said substrate by a chemical-mechanic-polishing process, said removing ensuring that said set of particles are not connected to each other by said material.

17. The method of claim 11, wherein filling said set of openings with said material comprises applying a physical vapor deposition (PVD) process to deposit said material layer-by-layer on top of a surface of said set of openings in said substrate.

18. The method of claim 11, wherein said set of particles has a size larger than 1 nm.

19. A method comprising:
creating a set of openings in a substrate, said set of openings having a set of shapes that are complimentary to shapes of a set of nano-parts, said nano-parts having a size between 1 nm and 1000 nm;
lining said set of openings with a thin layer of oleic acid of a single molecule thickness;
depositing a metal-oxide material inside said set of openings to form said set of nano-parts;
immersing said substrate together with said set of nano-parts inside a solution;
applying a supersonic vibration to said substrate via said solution causing said set of nano-parts to detach from said substrate; and
separating said set of nano-parts from said substrate.

20. The method of claim 19, wherein depositing said metal-oxide material comprises applying an electron-beam deposition, an ion-assisted deposition, or an ion-beam sputtering process in filling said metal-oxide material, layer-by-layer, inside said set of openings.
